(19) United States
(12) Patent Application Publication
(10) Pub. No.: US 2008/0035060 A1
(43) Pub. Date: Feb. 14, 2008

(54) Chemical vapor deposition reactor

(75) Inventors: Ming-Hui Wang, Taipei City (TW); Hsiao-Kuo Chang, Taoyuan City (TW); Kuan-Hung Lin, Banciao City (TW)

Correspondence Address: BACON & THOMAS, PLLC, 625 SLATERS LANE, FOURTH FLOOR, ALEXANDRIA, VA, 22314, US

(73) Assignee: Kinik Company, Taipei (TW)

(21) Appl. No.: 11/594,213

(22) Filed: Nov. 8, 2006

(30) Foreign Application Priority Data
Aug. 9, 2006 (TW) 095129183

(51) Int. Cl. C23C 16/00

(52) U.S. Cl. 118/723 HC

(57) ABSTRACT

A CVD (chemical vapor deposition) reactor having a vertical coating plane and power source-controlled hot filaments is disclosed. The CVD reactor has a chamber, one or a number of rotating electrodes, hot filaments, and a rotating power source at each rotating electrode. When the hot filaments expand due to hot, the rotating power source rotates the rotating electrode(s) to stretch the hot filaments and to further maintain the predetermined tension of the hot filaments, thereby preventing vibration of the hot filaments so as not to interfere with the performance of the coating work and not to damage the substrate upon flowing of a gas in the chamber.

### BACKGROUND OF THE INVENTION

1. Field of the Invention

The present invention relates to an equipment for chemical vapor deposition and more particularly, to a CVD (chemical vapor deposition) reactor having a vertical coating plane and power source-controlled hot filaments.

2. Description of Related Art

Hot filament CVD (HFCVD) is a kind of chemical vapor deposition. Because of the advantages of high covering power, high uniformity, high purity, and big area deposition, hot filament CVD is intensively used in making diamond thin films and polysilicon materials.

Basically, hot filament CVD (HFCVD) uses the surface high temperature of hot filaments in the chamber of a reactor to cause pyrolysis (thermal cracking) of the reaction gas that passes through the hot filaments so that atoms are deposited to form a thin film on the substrate.

In actual manufacturing application, the reaction temperature of the substrate in the reaction chamber of the reactor must be controlled within the optimal manufacturing conditions so that the quality parameters of purity, thickness and uniformity of the deposited thin film can be controlled.

However, during the deposition operation of the hot filament CVD reactor, the hot filament surface temperature in the reaction chamber may be over 2400° C. (hot filament temperature may be changed subject to the material to be coated). The hot filaments expand under this high temperature, and may vibrate subject to the flowing of the reaction gas, resulting in uneven thickness of deposited thin film or breaking of the hot filaments to damage the substrate.

In order to eliminate the aforesaid problem, hot filaments and the substrate may be set in vertical to downward suspension due to the effect of the gravity. However, this mounting method still cannot eliminate the expansion problem of hot filaments due to high temperature and flowing of a gas in the chamber of the reaction.

Therefore, it is desirable to provide a chemical vapor deposition reactor that eliminates the aforesaid problems.

### SUMMARY OF THE INVENTION

The present invention has been accomplished under the circumstances in view. According to one aspect of the present invention, the chemical vapor deposition react or comprises a chamber, at least two electrodes, a plurality of hot filaments, and a rotating power source.

The chamber has an enclosed space, an inside bearing surface in the enclosed space, and at least one substrate placed on the inside bearing surface in the enclosed space in a vertical position. The at least two electrodes are arranged in the enclosed space inside the chamber, including at least one rotating electrode. The hot filaments are arranged on the at least two electrodes in parallel to provide a vertical coating plane. The hot filaments each have two distal ends respectively connected to the at least two electrodes. The hot filaments are respectively spaced from the at least one substrate at a predetermined distance. Each hot filament has a predetermined tension. The rotating power source is adapted to rotate the at least one rotating electrode in one direction so as to maintain the predetermined tension.

Thus, when the hot filaments expand due to a significant temperature change during the coating work in the chamber, the rotating electrode is rotated to stretch the hot filaments, thereby preventing vibration of the hot filaments so as not to interfere with the performance of the coating work and not to damage the substrate upon flowing of a gas in the chamber.

Further, the rotating power source can be an electric motor, a pneumatic cylinder, a hydraulic cylinder, or any of a variety of other equivalent devices. Spring or weight may be used to substitute for the rotating power source to maintain the predetermined tension of the hot filaments, preventing vibration of the hot filaments.

The invention further comprises at least one sensor adapted to detect change of the distance between the hot filaments and the substrate and to output a corresponding detection signal. The sensor can be an optical sensor, a thermocouple sensor, or any of a variety of other equivalent sensor.

The chemical vapor deposition reactor further comprises a controller adapted to receive the detection signal outputted from the at least one optical sensor and to control the operation of the rotating power source subject to the detection signal. Alternatively, the detection signal may be used to directly control the operation of the rotating power source without through the controller.

Further, the sensor can be a thermocouple sensor adapted to detect variation of the temperature of the hot filaments and to output a corresponding detection signal to the controller for controlling the operation of the rotation power source device.

Further, the sensor can be a stress sensor adapted to detect variation of the tension of the hot filaments and to output a corresponding detection signal to the controller for controlling the operation of the rotation power source device.

Further, each hot filament can be formed of a plurality of twisted hot wires to enhance the tensile strength, toughness, and high temperature physical performance of the hot filaments, and to improve heat energy distribution stability, i.e., to improve thermal stability and reduce expansion or contraction of the hot filaments upon a drastic temperature change.

The hot filaments may be arranged in parallel in horizontal direction or in vertical direction.

### BRIEF DESCRIPTION OF THE DRAWINGS

FIG. 1 is a schematic drawing of a chemical vapor deposition reactor in accordance with a first embodiment of the present invention.

FIG. 2 is a schematic drawing of a chemical vapor deposition reactor in accordance with a second embodiment of the present invention.

FIG. 3 is a schematic drawing of a chemical vapor deposition reactor in accordance with a third embodiment of the present invention.

FIG. 4 is a schematic drawing of a chemical vapor deposition reactor in accordance with a fourth embodiment of the present invention.

FIG. 5A is an enlarged view of a part of FIG. 1, showing the structure of the hot filament.

FIG. 5B is an enlarged view of a part of FIG. 3, showing the structure of the hot filament.

### DETAILED DESCRIPTION OF THE PREFERRED EMBODIMENT

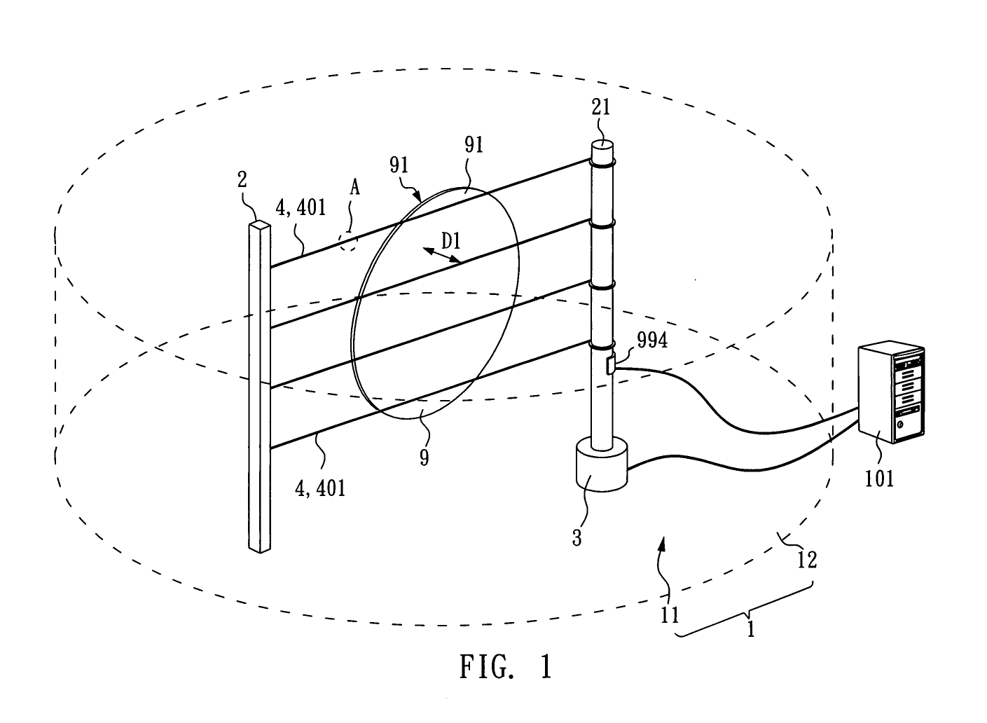

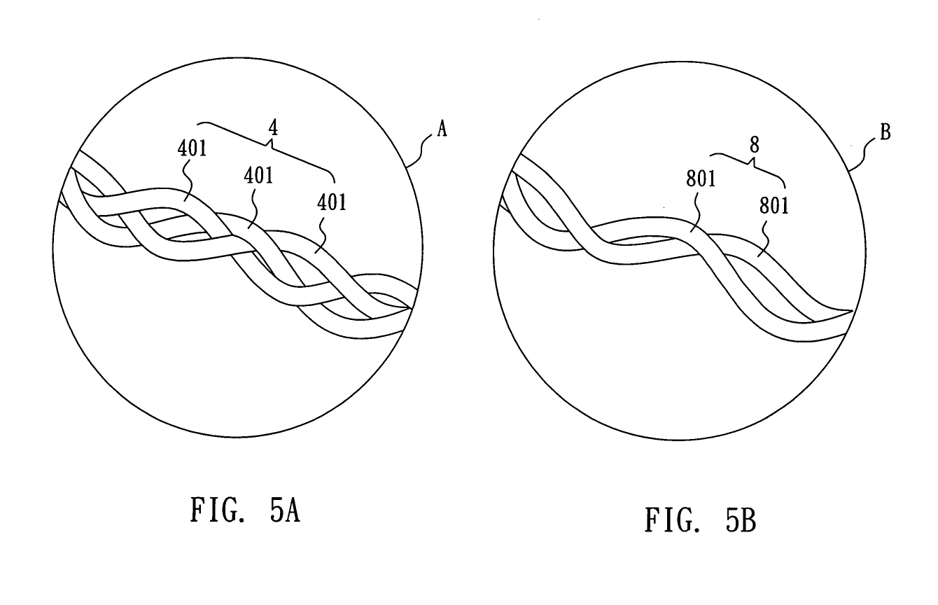

FIG. 1 is a schematic drawing of a chemical vapor deposition reactor in accordance with a first embodiment of the present invention. FIG. 5A is an enlarged view of a part of FIG. 1, showing the structure of the hot filament. As shown in FIG. 1, the chemical vapor deposition reactor comprises a chamber 1 for a coating work. The chamber 1 defines therein an enclosed space 11 and an inside bearing surface 12. A substrate 9 for the coating work of chemical deposition is placed on the inside bearing surface 12 in vertical for coating. The substrate 9 has one single work surface or two opposite work surfaces 91 thereof set for coating.

Further, two electrodes 2 and 21 are vertically mounted inside the enclosed space 11. The electrode at the left side is a fixed electrode 2. The electrode at the right side is a rotating electrode 21. The rotating electrode 21 is mounted on a rotating power source 3 and rotatable by the rotating power source 3.

As illustrated in FIG. 1, four hot filaments 4 are respectively connected with the respective two distal ends to the fixed electrode 2 and the rotating electrode 21. The hot filaments 4 are arranged in parallel to provide a coating plane perpendicular to the inside bearing surface 12 of the chamber 1 of the chemical vapor deposition reactor, and kept apart from one work surface 91 of the substrate 9 at a predetermined distance D1. Further, each hot filament 4 has a predetermined tension. Further, as shown in FIG. 5A, each hot filament 4 is comprised of three hot wires 401 that are twisted, thereby enhancing the tensile strength, toughness, and high temperature physical performance of the hot filaments 4, and improving heat energy distribution stability, i.e., improving thermal stability to reduce expansion or contraction of the hot filaments 4 upon a drastic temperature change.

According to this embodiment, the rotating power source 3 is an electric motor that outputs a rotary driving force. Alternatively, a pneumatic cylinder, a hydraulic cylinder, or any of a variety of other equivalent rotating power sources may be used as a substitute. Further, a stress sensor 994 is mounted on the rotating electrode 21 to detect the tension of every hot filament 4 and to output a corresponding detection signal to an external controller 101 for computing so that the computed result is used to control the operation of the rotating power source 3 in rotating the rotating electrode 21 in a particular direction, thereby maintaining the tension of every hot filament 4 at a predetermined value.

Thus, when the hot filaments 4 expand due to a significant temperature change during the coating work in the chamber 1, the rotating electrode 21 is rotated to stretch the hot filaments 4 and to further maintain the predetermined distance D1 between the hot filaments 4 and the adjacent work surface 91 of the substrate 9, thereby preventing vibration of the hot filaments 4 so as not to interfere with the performance of the coating work and not to damage the substrate 9 upon flowing of a gas in the chamber 1.

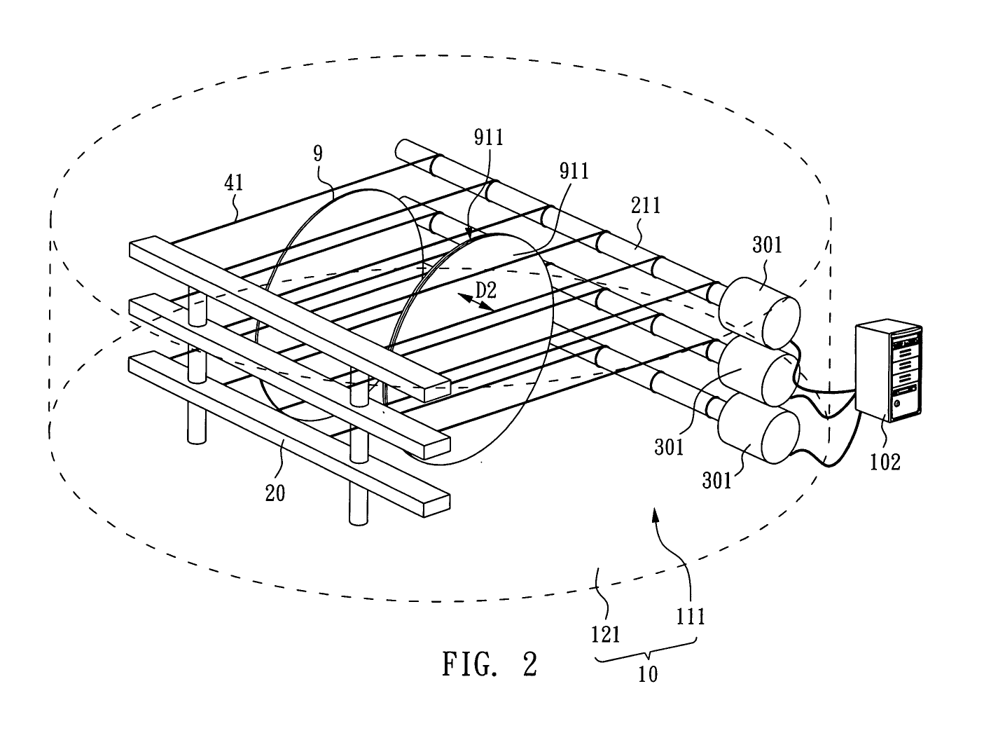

FIG. 2 is a schematic drawing of a chemical vapor deposition reactor in accordance with a second embodiment of the present invention. According to this second embodiment, the hot filaments 41 are arranged in parallel to the inside bearing surface 121 inside the enclosed space 111 of the chamber 10. However, the extending direction of the electrodes according to this second embodiment is different from the extending direction of the rotating electrode 211 of the aforesaid first embodiment.

As shown in FIG. 2, this second embodiment comprises three rotating electrodes 211 arranged in parallel to the inside bearing surface 121 in the enclosed space 111 at one side at three different elevations, three fixed electrodes 20 arranged in parallel to the inside bearing surface 121 in the enclosed space 111 at three different elevations corresponding to the rotating electrodes 211, and three sets of hot filaments 41 respectively connected between the rotating electrodes 211 and the fixed electrode 20 and arranged in parallel at three different elevations. According to this second embodiment, each rotating electrode 211 has connected thereto six hot filaments 41. Further, the rotating electrodes 211 are respectively connected to a respective rotating power source 301. Further, a plurality of substrates 9 are placed on the inside bearing surface 121 in the enclosed space 111 of the chamber 10 in vertical and extending across the three elevations of the three sets of hot filaments 41. Thus, the substrate 9 at the left side in FIG. 2 has the two opposite work surfaces 911 set for coating, and the two abutted substrates 9 at the right side in FIG. 2 have the respective outer work surface 911 set for coating.

According to this second embodiment, the rotating power sources 301 are electric motors that are electrically connected to an external controller 102. The controller 102 controls rotation of the rotating power sources 301 in one direction subject to the computing of its internal function, maintaining the tension of each hot filament 41 at the predetermined value. Therefore, when the hot filaments 41 expand due to hot, the respective rotating electrodes 211 are rotated to stretch the respective hot filaments 41 and to further maintain the predetermined distance D2 between each work surface 911 of each substrate 9 and the adjacent hot filaments 41, preventing vibration of the hot filaments 4 so as not to interfere with the performance of the coating work and not to damage the substrate 9 upon flowing of a gas in the chamber 1. Therefore, this second embodiment achieves the same various effects as the aforesaid first embodiment does. Further, this second embodiment is capable of coating multiple substrates 9 at one time.

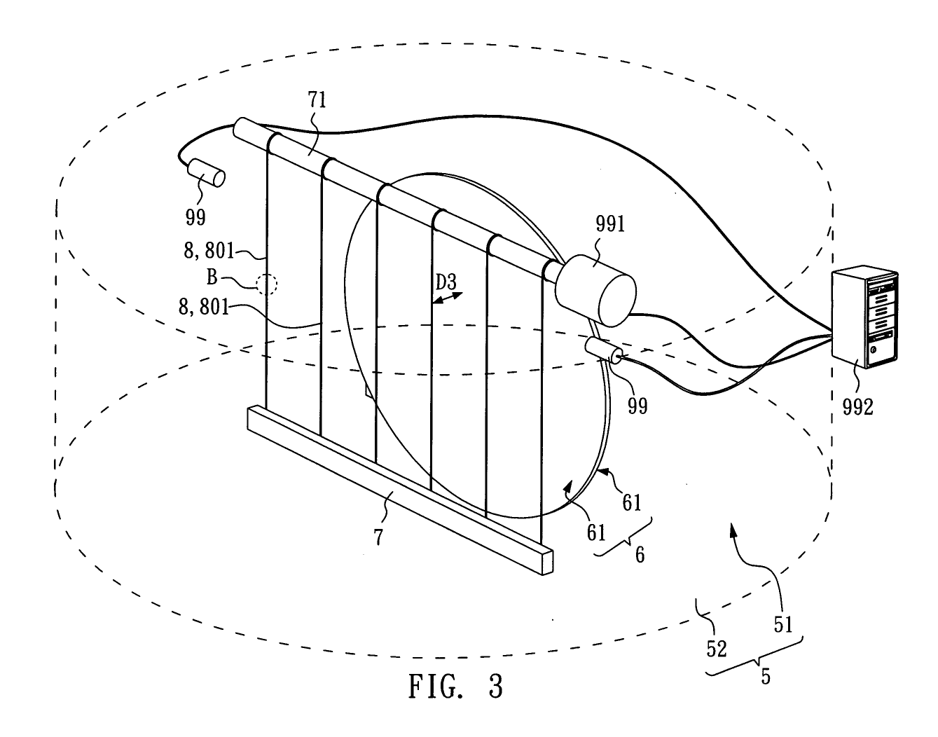

FIG. 3 is a schematic drawing of a chemical vapor deposition reactor in accordance with a third embodiment of the present invention. FIG. 5B is an enlarged view of a part of FIG. 3, showing the structure of the hot filament.

As shown in FIG. 3, this third embodiment comprises a chamber 5. The chamber 5 has an enclosed inside space 51 and an inside bearing surface 52. A substrate 6 is placed on the inside bearing surface 52 in vertical for coating. The substrate 6 has one single work surface or two opposite work surfaces 61 for coating. Further, two electrodes 7 and 71 are provided inside the enclosed inside space 51. According to this embodiment, the rotating electrode 71 is spaced above the fixed electrode 7 and connected with its one end to a rotating power source 991, which is connected to an external controller 992 and controlled by the controller 992 to rotate the rotating electrode 71. According to this embodiment, the rotating power source 991 is an electric motor. However, a pneumatic cylinder, a hydraulic cylinder, or any of a variety of other equivalent rotating power sources may be used as a substitute.

As shown in FIG. 3, there are six hot filaments 8 respectively connected between the fixed electrode 7 and the rotating electrode 71 and arranged in parallel, providing a coating plane. Each hot filament 8 extends vertically downwards from the rotating electrode 71, and kept from the adjacent work surface 61 of the substrate 6 at a predetermined distance D3. Further, each hot filament 8 has a predetermined tension. Further, as shown in FIG. 5B, each hot filament 8 is formed of two twisted hot wires 801, thereby enhancing the tensile strength, toughness, and high temperature physical performance of the hot filaments 8, and improving heat energy distribution stability, i.e., improving thermal stability to reduce expansion or contraction of the hot filaments 8 upon a drastic temperature change.

Further, a pair of sensors 99 is provided inside the enclosed inside space 51 to detect variation of the predetermined distance D3 between the work surface 61 of the substrate 6 and each hot filament 8, and to output a corresponding detection signal to the controller 992 for computing. According to this embodiment, the sensors 99 are optical sensors. Alternatively, infrared sensors and tension sensors may be used to detect change of the tension of the hot filaments 8.

According to this embodiment, the optical sensors 99 output a detection signal to the external controller 992 for computing so that the controller 992 controls the rotating power source 991 to rotate the rotating electrode 71 in one direction subject to the computed result, thereby maintaining the predetermined tension of the hot filaments 8. Therefore, when the hot filaments 8 expand due to a variation of temperature upon a chemical reaction during the coating work, the rotating electrode 71 is properly rotated to stretch the hot filaments 8, thereby maintaining the predetermined tension of the hot filaments 8 and the predetermined distance D3 between the work surface 61 of the substrate 6 and the hot filaments 8, and therefore this embodiment prevents vibration of the hot filaments 8 to interfere with the performance of the coating work or to damage the substrate 6 upon flowing of a gas in the chamber 5.

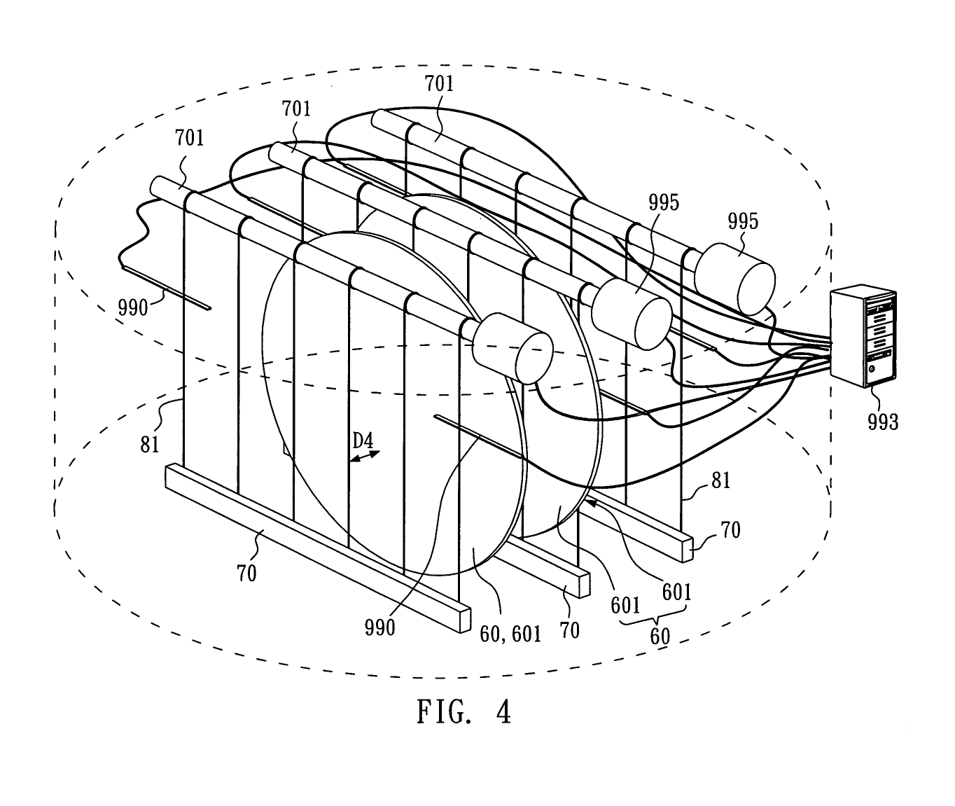

FIG. 4 shows a chemical vapor deposition reactor in accordance with a fourth embodiment of the present invention. This embodiment is substantially similar to the aforesaid third embodiment. However, this fourth embodiment can coat multiple substrates 60 at one time.

As shown in FIG. 4, three rotating electrodes 701 and three fixed electrodes 70 constitute two coating zones, and two substrates 60 are respectively set in the two coating zones. Further, each rotating electrode 701 has connected thereto six hot filaments 81 that extend downwards to one corresponding fixed electrode 70.

Further, as shown in FIG. 4, each rotating electrode 701 has one end connected to a respective rotating power source 995 and rotatable by the associating rotating power source 995. The rotating power sources 995 according to this embodiment are electric motors.

Further, three pairs of sensors 990 are provided to detect the variation of temperature of every hot filament 81 and to output a corresponding detection signal. According to this embodiment, the sensors 990 are thermocouple sensors that are electrically connected to an external controller 993. The three pairs of sensors 990 output the respective detection signal to the controller 993 for computing, so that the controller 993 controls the rotating power sources 995 to rotate the associating rotating electrodes 701 and to further maintain the predetermined tension of the hot filaments 81.

Therefore, in addition of the effect of maintaining the predetermined distance D4 between the work surface 601 of the substrate 60 and the hot filaments 81 to prevent vibration of the hot filaments 81 upon flowing of a gas in the chamber 5 as what the aforesaid third embodiment provides, this fourth embodiment allows coating of multiple substrates 60 at one time to short the total working time and to improve the working efficiency.

Although the present invention has been explained in relation to its preferred embodiments, it is to be understood that many other possible modifications and variations can be made without departing from the spirit and scope of the invention as hereinafter claimed.

What is claimed is:

1. A chemical vapor deposition reactor comprising:
a chamber, said chamber having an enclosed space, an inside bearing surface in said enclosed space, and at least one substrate placed on said inside bearing surface in said enclosed space in a vertical position;
at least two electrodes arranged in said enclosed space inside said chamber, said at least two electrodes including at least one rotating electrode;
a plurality of hot filaments arranged on said at least two electrodes in parallel to provide a vertical coating plane, said hot filaments each having two distal ends respectively connected to said at least two electrodes, said hot filaments being respectively spaced from said at least one substrate at a predetermined distance, said hot filaments each having a predetermined tension; and
a rotating power source adapted to rotate said at least one rotating electrode in one direction so as to maintain the predetermined tension of said hot filaments.

2. The chemical vapor deposition reactor as claimed in claim 1, wherein said rotating power source is selected from one of the rotating power sources including an electric motor, a pneumatic cylinder, and a hydraulic cylinder.

3. The chemical vapor deposition reactor as claimed in claim 1, further comprising at least one optical sensor adapted to detect variation of said predetermined distance and to outputs a corresponding detection signal.

4. The chemical vapor deposition reactor as claimed in claim 3, further comprising a controller adapted to receive the detection signal outputted from said at least one optical sensor and to control the operation of said rotating power source subject to the detection signal.

5. The chemical vapor deposition reactor as claimed in claim 3, wherein said detection signal directly controls the operation of said rotating power source.

6. The chemical vapor deposition reactor as claimed in claim 1, further comprising at least one thermocouple sensor adapted to detect variation of the temperature of said hot filaments and to output a corresponding detection signal.

7. The chemical vapor deposition reactor as claimed in claim 5, further comprising a controller adapted to receive the detection signal outputted from said at least one thermocouple sensor and to control the operation of said rotating power source subject to the detection signal.

8. The chemical vapor deposition reactor as claimed in claim 5, wherein said detection signal directly controls the operation of said rotating power source.

9. The chemical vapor deposition reactor as claimed in claim 1, further comprising at least one stress sensor adapted to detect variation of said predetermined tension and to output a corresponding detection signal.

10. The chemical vapor deposition reactor as claimed in claim 7, further comprising a controller adapted to receive the detection signal outputted from said at least one stress sensor and to control the operation of said rotating power source subject to the detection signal.

11. The chemical vapor deposition reactor as claimed in claim 7, wherein said detection signal directly controls the operation of said rotating power source.

12. The chemical vapor deposition reactor as claimed in claim 1, wherein said hot filaments each are comprised of a plurality of twisted hot wires.

13. The chemical vapor deposition reactor as claimed in claim 1, wherein said hot filaments are arranged in horizontal in a parallel manner.

14. The chemical vapor deposition reactor as claimed in claim 1, wherein said hot filaments are arranged in vertical in a parallel manner.
